(19) United States
(12) Patent Application Publication
(10) Pub. No.: US 2026/0072598 A1
(43) Pub. Date: Mar. 12, 2026

(54) MEMORY DEVICE, OPERATION METHOD OF MEMORY DEVICE, MEMORY SYSTEM, AND CHIP

(71) Applicant: YANGTZE MEMORY TECHNOLOGIES CO., LTD., Wuhan (CN)

(72) Inventors: Xuening JIA, Wuhan (CN); ZhiChao DU, Wuhan (CN); Shengyang FANG, Wuhan (CN)

(21) Appl. No.: 19/063,027

(22) Filed: Feb. 25, 2025

(30) Foreign Application Priority Data
Sep. 12, 2024 (CN) 202411281664X

(51) Int. Cl. G06F 3/06

(52) U.S. Cl. CPC G06F 3/0619; G06F 3/0659; G06F 3/0679

(57) ABSTRACT

The present application discloses a memory device, an operation method of a memory device, a memory system. The memory device includes a memory array and a peripheral circuit. The peripheral circuit is configured to: use a first read parameter to read a plurality of correction parameter copies of a correction parameter from the memory array in response to receiving a power-on signal, wherein the plurality of correction parameter copies are copies stored with respect to the correction parameter; and correct the plurality of correction parameter copies to output the correction parameter, wherein the correction parameter is for adjusting the first read parameter to obtain a second read parameter when reading the memory array. The plurality of parameter copies obtained by reading are corrected by a multiple modular redundancy circuit such that an accurate correction parameter with a small error probability is determined.

### CROSS-REFERENCE TO RELATED APPLICATIONS

The present application claims priority to Chinese Patent Application No. 202411281664X, which was filed Sep. 12, 2024, and is hereby incorporated herein by reference in its entirety.

### TECHNICAL FIELD

The present application relates to the technical field of memory, and particularly to a memory device, an operation method of a memory device, a memory system, and a chip.

### BACKGROUND

A memory device typically comprises a memory array that comprises a memory cell for storing data. In a data reading process of the memory device, a read parameter is usually acquired first, such as a reference voltage, a reference current, etc., and then the read parameter is employed to read data stored in the memory cell.

The data reading process of the memory device typically comprises the operations of address selection, address decoding, memory cell selection, data reading, and data outputting, etc.

### SUMMARY

The present application provides a memory device, an operation method of a memory device, a memory system, and a chip. The technical solutions are as follows:

In an aspect, provided is a non-volatile memory device, comprising a memory array and a peripheral circuit;
wherein the peripheral circuit is configured to:
use a first read parameter to read a plurality of correction parameter copies of a correction parameter from the memory array in response to receiving a power-on signal, wherein the plurality of correction parameter copies are copies stored with respect to the correction parameter; and
correct the plurality of correction parameter copies of the correction parameter to output the correction parameter, wherein the correction parameter is for adjusting the first read parameter to obtain a second read parameter when reading the memory array.

In one optional example, the non-volatile memory device comprises a one time program (OTP) memory device.

In one optional example, the peripheral circuit comprises a multiple modular redundancy sub-circuit; and
the peripheral circuit is further configured to:
correct, by the multiple modular redundancy sub-circuit, the plurality of correction parameter copies to output the correction parameter.

In one optional example, the multiple modular redundancy sub-circuit comprises a voter; and
the peripheral circuit is further configured to:
determine, by the voter in the multiple modular redundancy sub-circuit, the correction parameter from the plurality of correction parameter copies.

In one optional example, each correction parameter copy comprises n first read sub-addresses; a parameter value of an i^{th} correction parameter copy is a combination of numerical values read from the n first read sub-addresses corresponding to the i^{th} parameter copy; and
the peripheral circuit is further configured to:
acquire a numerical value read from a k^{th} first read sub-address of each correction parameter copy to obtain a plurality of numerical values, and determine, from the plurality of numerical values, a numerical value occurring most frequently as a value of an k^{th} bit of the correction parameter, wherein i, n, and k are positive integers, and k≤n.

In one optional example, the peripheral circuit is further configured to:
acquire a plurality of first read addresses, wherein an i^{th} first read address is for indicating a location of the i^{th} correction parameter copy stored in the memory array, and i is a positive integer; and
use the first read parameter to read the plurality of first read addresses in the memory array.

In one optional example, the number of the correction parameter copies corresponding to the correction parameter corresponds to the number of modules for performing voting in the multiple modular redundancy sub-circuit.

In one optional example, the peripheral circuit further comprises a register unit; and
the peripheral circuit is further configured to:
use the first read parameter to read a plurality of correction parameter copies of an m^{th} correction parameter from the memory array, wherein m is a positive integer;
correct the plurality of correction parameter copies of the m^{th} correction parameter to output the m^{th} correction parameter; store the m^{th} correction parameter to the register unit to obtain first m correction parameters;
if the correction parameters are not read completely, read a plurality of correction parameter copies of an (m+1)^{th} correction parameter from the memory array;
correct the plurality of correction parameter copies of the (m+1)^{th} correction parameter to output the (m+1)^{th} correction parameter; and store the (m+1)^{th} correction parameter to the register unit to obtain first m+1 correction parameters until all the correction parameters are read completely.

In one optional example, the peripheral circuit is further configured to:
adjust the first read parameter with the correction parameter to obtain the second read parameter; and
use the second read parameter to read an operating parameter in the memory array, wherein the operating parameter is data stored in the memory device for indicating the operating of a chip.

In one optional example, the peripheral circuit is further configured to:
acquire a second read address, wherein the second read address is for indicating a location of the operating parameter stored in the memory array; and
use the second read parameter to read the operating parameter from the second read address in the memory array.

In another aspect, provided is a volatile memory device, coupled with a non-volatile memory device and comprising a memory array and a peripheral circuit;
wherein the peripheral circuit is configured to:
after the volatile memory device is powered on, send a power-on signal to the non-volatile memory device, wherein the power-on signal is for instructing the non-volatile memory device to use a first read parameter to read a plurality of correction parameter copies of a correction parameter from a memory array of the non-volatile memory device, and correct the plurality of correction parameter copies of the correction parameter to output a correction parameter, and determine a second read parameter based on the correction parameter and then read an operating parameter with the second read parameter;
receive the operating parameter sent by the non-volatile memory device; and
read the memory array based on the operating parameter.

In one optional example, the peripheral circuit is coupled with a peripheral circuit of the non-volatile memory device; and
the peripheral circuit is further configured to:
after the volatile memory device is powered on, send the power-on signal to the peripheral circuit of the non-volatile memory device.

In one optional example, the peripheral circuit is further configured to:
read the memory array based on a read voltage, a read current, and a time delay in the operating parameter.

In one optional example, the non-volatile memory device coupled with the volatile memory device is implemented as a one time program (OTP) memory device.

In further another aspect, provided is an operation method of a non-volatile memory device, comprising:
using a first read parameter to read a plurality of correction parameter copies of a correction parameter from the memory array in response to receiving a power-on signal, wherein the plurality of correction parameter copies are copies stored with respect to the correction parameter; and
correcting the plurality of correction parameter copies to output the correction parameter, wherein the correction parameter is for adjusting the first read parameter to obtain a second read parameter when reading the memory array.

In one optional example, the non-volatile memory device comprises a one time program (OTP) memory device.

In one optional example, the using the first read parameter to read the plurality of correction parameter copies from a first memory array of the memory device comprises:
acquiring a plurality of first read addresses, wherein an i^{th} first read address is for indicating a location of the i^{th} correction parameter copy stored in the memory array, and i is a positive integer; and
using the first read parameter to read from the plurality of first read addresses in the memory array.

In one optional example, each correction parameter copy comprises n first read sub-addresses; a parameter value of an i^{th} correction parameter copy is a combination of numerical values read from the n first read sub-addresses corresponding to the i^{th} parameter copy; and
the correcting the plurality of correction parameter copies to output the correction parameter comprises:
acquiring a numerical value read from a k^{th} first read sub-address of each correction parameter copy to obtain a plurality of numerical values; and
determining, from the plurality of numerical values, a numerical value occurring most frequently as a value of an i^{th} bit of the correction parameter, wherein i, n, and k are positive integers, and k≤n.

In one optional example, the non-volatile memory device comprises a multiple modular redundancy sub-circuit; and the number of the stored correction parameter copies corresponds to the number of modules for performing voting in the multiple modular redundancy sub-circuit.

In one optional example, the method further comprises:
using the first read parameter to read a plurality of correction parameter copies of an m^{th} correction parameter from the memory array, wherein m is a positive integer;
correcting the plurality of correction parameter copies of the m^{th} correction parameter to output the m^{th} correction parameter; store the m^{th} correction parameter to obtain first m correction parameters;
if the correction parameters are not read completely, reading a plurality of correction parameter copies of an (m+1)^{th} correction parameter from the memory array;
correcting the plurality of correction parameter copies of the (m+1)^{th} correction parameter to output the (m+1)^{th} correction parameter; and storing the (m+1)^{th} correction parameter to obtain first m+1 correction parameters until all the correction parameters are read completely.

In one optional example, after outputting the correction parameter, the method further comprises:
adjusting the first read parameter with the correction parameter to obtain the second read parameter; and
using the second read parameter to read an operating parameter in the memory array, wherein the operating parameter is data stored in the non-volatile memory device for indicating the operating of a chip.

In one optional example, the using the second read parameter to read the operating parameter in the memory array comprises:
acquiring a second read address, wherein the second read address is for indicating a location of the operating parameter stored in the memory array; and
using the second read parameter to read the operating parameter from the second read address in the memory array.

In still another aspect, provided is a memory system, comprising:
one or more non-volatile memory devices or volatile memory devices described in the above-mentioned examples, and
a memory controller coupled to the non-volatile memory devices or the volatile memory devices and configured to control the non-volatile memory devices or the volatile memory devices.

In yet another aspect, provided is a chip, comprising:
one or more non-volatile memory devices or volatile memory devices described in the above-mentioned examples.

The technical solutions provided by the present application may comprise the following beneficial effects:

When reading a memory device after power-on reset, a correction parameter related to a read operation is firstly read according to a default read parameter, and since the correction parameter is stored as a plurality of parameter copies, the plurality of parameter copies are read, and the read plurality of parameter copies are corrected by a multiple modular redundancy circuit such that an accurate correction parameter with a small error probability is determined. A default read parameter is adjusted with the correction parameter to obtain a read parameter for reading other operating parameters. The accuracy of reading the operating parameters is improved, and the problem of low reliability of reading from an OTP memory device at a power-on stage is avoided.

### BRIEF DESCRIPTION OF THE DRAWINGS

In order to describe the technical solutions in examples of the present application more clearly, the drawings required to be used in the examples will be simply introduced below. It is apparent that the drawings in the following descriptions are only some examples of the present application. Those of ordinary skill in the art may further obtain other drawings according to these drawings without creative work.

FIG. 1 is a schematic structural diagram of an OTP memory device provided by one example of the present application;

FIG. 2 is a schematic diagram of a read flow provided by one example of the present application;

FIG. 3 is a flow diagram of an operation method of a non-volatile memory device provided by one example of the present application;

FIG. 4 is a schematic diagram of a multiple modular redundancy circuit provided based on the example shown in FIG. 3;

FIG. 5 is a schematic diagram of OTP current control provided based on the example shown in FIG. 3;

FIG. 6 is a flow diagram of an operation method of a non-volatile memory device provided by another example of the present application;

FIG. 7 is a schematic diagram of a read flow provided based on the example shown in FIG. 6;

FIG. 8 is a flow diagram of an operation method of a non-volatile memory device provided by another example of the present application;

FIG. 9 is a schematic structural diagram of a memory device provided by an example of the present application;

FIG. 10 is a schematic structural diagram of a memory system provided by an example of the present application; and

FIG. 11 is a schematic structural diagram of a memory device provided by another example of the present application.

### DETAILED DESCRIPTION

Implementations of the present application are further described in detail below with reference to the drawings.

Firstly, terms involved in examples of the present application are introduced.

One Time Program (OTP) memory device: it is a non-volatile memory device, which has at least the following characteristics: 1, programmability: the OTP memory device can be programmed in the manufacturing process, and once it has been programmed, contents therein cannot be changed. A program process may be implemented by methods such as electron injection or connector burndown, etc. 2, non-volatility: the OTP memory device is a non-volatile memory device. For example, the OTP memory device still can retain the storage of data after being powered off or restarted. 3, high reliability: since the data stored cannot be changed after programming, the OTP memory device has high reliability. It will not be affected by factors such as electromagnetic interference, temperature variation or power failure, etc. 4, low power consumption: the OTP memory device typically has low power consumption because the OTP memory device does not need an external power source to retain the stored data.

The working principle of the OTP memory device is relatively simple. In the program process of the OTP memory device, electron injection or connector burndown will change the electrical properties of a memory cell such that the memory cell logically represent a particular data bit. These data bits may be read but cannot be changed.

In conclusion, the OTP memory device is a non-volatile memory device that can only be programmed once. It has been widely applied in many applications, such as security authentication, key storage, and firmware code storage, etc.

Multiple modular redundancy circuit: it can be implemented as a triple modular redundancy (TMR) circuit, a quadruple modular redundancy (QMR) circuit, etc. The number of modules for performing voting in the multiple modular redundancy circuit is not limited in the examples of the present application.

The multiple modular redundancy circuit improves the system reliability by increasing redundancy elements or modules. In examples of the present application, the multiple modular redundancy circuit comprises a plurality of modules for performing voting. A correction parameter is corrected by the plurality of modules for performing voting to obtain a corrected correction parameter. Thus, a read parameter is adjusted with the corrected correction parameter to obtain an adjusted read parameter, and data stored in a memory array is read based on the adjusted read parameter. As a result, the accuracy of reading the memory array is improved; the problem of errors in data reading caused by the influences of process voltage temperature (PVT) when powering on is avoided; and the accuracy and efficiency of data reading are improved.

Power-on reset read (POR_READ): it refers to a behavior of reading and accessing a non-volatile memory device during system power-on reset.

A read method of a memory device provided by examples of the present application may be applied to a non-volatile memory device. The non-volatile memory may be an OTP memory device.

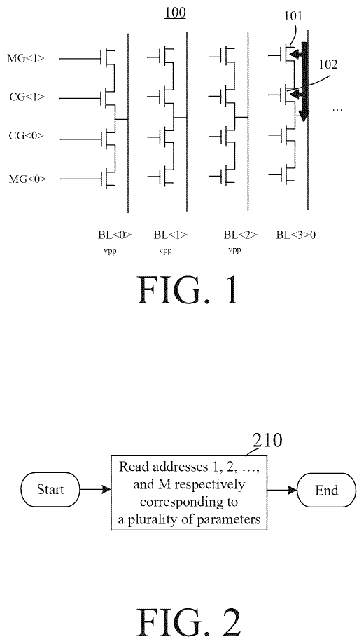

In examples of the present application, the non-volatile memory device is implemented as the OTP memory device for example. FIG. 1 is a schematic structural diagram of an OTP memory device provided by one example of the present application.

The OTP memory device comprises a peripheral circuit and a memory array. The peripheral circuit is configured to control an operating process of the OTP memory device. The memory array is configured to store data.

As shown in FIG. 1, it is a schematic diagram mainly showing the memory array 100 in the OTP memory device. The memory array 100 comprises a plurality of memory cells arranged in an array.

The memory cells in the OTP memory device mainly include a control grid (CG) cell and a memory grid (MG) cell. The MG cell is a thick grid oxide device broken down by a high voltage. The MG cell is programmable. When programmed successfully, the MG cell will be in a permanent on state.

The memory array of the OTP memory device is implemented as a two-dimensional memory array comprising rows and columns, wherein taking the memory array 100 shown in FIG. 1 for example, a memory cell is coupled in a column direction with a bit line (BL), and the memory cell is coupled in a row direction with a control grid (CG) or a memory grid (MG), wherein the control grid cell is coupled in the row direction with the CG, and the memory grid cell is coupled in the row direction with the MG. A specified memory cell in the memory array can be located by means of the CG, the MG, and the BL.

As shown in FIG. 1, when bit line BL<3> is selected, after control grid CG<1> and memory grid MG<1> are selected, a memory cell 101 and a memory cell 102 are located for reading.

When POR_READ is performed, a decoder receives location data and decodes the location data to obtain a CG, an MG, and a BL coupled with a memory cell such that the memory cell to be read is located, and a read path is acquired based on the memory cell to be read. The read path comprises a sense amplifier that inputs 1 or 0 according to whether the memory cell is broken down.

The decoder and the sense amplifier described above are implemented as sub-circuits in the peripheral circuit.

In the related art, when POR_READ is performed, a read stage after power-on reset is typically performed directly. In an example, FIG. 2 illustrates a schematic diagram of a read flow provided by one example of the present application. The read flow comprises the following operation 210.

At operation 210, addresses 1, 2, . . . , and M respectively corresponding to a plurality of parameters are read.

For example, a plurality of addresses respectively corresponding to a plurality of parameters are read from a memory array of an OTP memory device with a default read parameter after power-on reset, and the plurality of parameters are read from the addresses respectively corresponding to the plurality of parameters. Parameter 1 is read from address 1, and parameter 2 from address 2, and parameter M from address M, M being a positive integer. The addresses are in one-to-one correspondence with the parameters.

The default read parameter is an uncorrected read parameter employed by the OTP memory device at the power-on reset stage. For example, regardless of a process, a voltage, and a temperature of a chip in which the OTP memory device resides, the default read parameter is for reading.

An operating parameter of operating of the chip is typically stored in the OTP memory device, such as a chip configuration parameter, an operating code, etc. In the power-on reset read operation of the OTP memory device, since the memory device is just powered on, the default read parameter programmed in a metal layer is employed to read data stored in the OTP memory device.

However, due to the influence of process voltage temperature (PVT), the default read parameter has a deviation, resulting in low accuracy of a power-on reset read result of the OTP memory device.

In examples of the present application, the peripheral circuit further comprises a multiple modular redundancy sub-circuit. When reading the parameter at the POR_READ stage, a plurality of correction parameter copies are read first, and the plurality of correction parameter copies are corrected by the multiple modular redundancy circuit to obtain a correction parameter. A read parameter for reading an OTP memory array is adjusted with the correction parameter to obtain a corrected read parameter, and the OTP memory array is read based on the corrected read parameter.

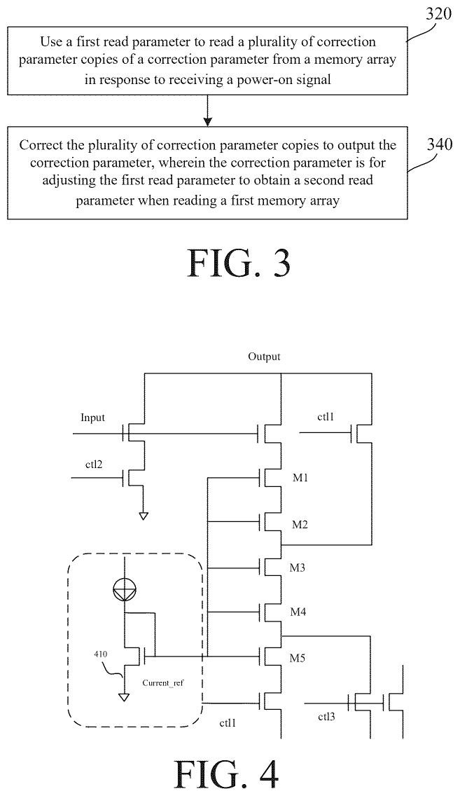

FIG. 3 illustrates an operation method of a non-volatile memory device provided by one example of the present application. The method may be performed by a peripheral circuit of the non-volatile memory device. The method comprises at least the following operations.

At operation 320, a first read parameter is employed to read a plurality of correction parameter copies of a correction parameter from a memory array in response to receiving a power-on signal.

The plurality of correction parameter copies are copies stored with respect to the correction parameter.

In some examples, when there are a plurality of correction parameters, each correction parameter corresponds to a plurality of correction parameter copies. In an example, taking each correction parameter corresponding to 3 correction parameter copies as an example, correction parameter a corresponds to correction parameter copy a′, correction parameter copy a″, and correction parameter copy a″Δ; and correction parameter b corresponds to correction parameter copy b′, correction parameter copy b″, and correction parameter copy b″Δ.

In some examples, the correction parameter copy is data written to a memory cell at the program stage of the non-volatile memory device. For each correction parameter, a plurality of correction parameter copies are written at the program stage. When the correction parameter copies are written, the plurality of correction parameter copies are written according to a value of the correction parameter. It may be construed as the plurality of correction parameter copies of the same correction parameter have the same value when being written.

In some examples, each correction parameter corresponds to different PVT conditions. In an example, correction parameter a corresponds to process 1, voltage 5 V, and temperature 40°, and correction parameter copy a′, correction parameter copy a″, and correction parameter copy a′″ are stored in a memory array with respect to the correction parameter a. Correction parameter b corresponds to process 1, voltage 10 V, and temperature 50°, and correction parameter copy b′, correction parameter copy b″, and correction parameter copy b′″ are stored in the memory array with respect to the correction parameter b.

Optionally, after the power-on signal is received, the non-volatile memory device first acquires PVT information of current operation, and acquires a storage location of a correction parameter having the highest matching degree with the PVT information, wherein the storage location refers to a location of a memory cell in the memory array where the plurality of correction parameter copies corresponding to the correction parameter are stored. Thus, the correction parameter copies of the correction parameter are read from the memory array based on the storage location.

Optionally, the power-on signal comprises the PVT information, or the non-volatile memory device reads the PVT information from a preset memory space based on the power-on signal. In an example, the non-volatile memory device reads the PVT information from a register of a chip (e.g., a volatile memory device) coupled with the non-volatile memory device based on the power-on signal, or the non-volatile memory device reads the PVT information from a register of its own peripheral circuit based on the power-on signal. The examples of the present application do not define the way of acquiring the PVT information.

In some examples, an operating program of the non-volatile memory device comprises a correspondence between PVT information and a storage location of correction parameter copies. The storage location of the correction parameter copies is located from the correspondence according to the read PVT information such that a plurality of correction parameter copies are read.

In this example, the above-mentioned non-volatile memory device comprises a one time program (OTP) memory device. The OTP memory device is coupled with other chips. In an example, the OTP memory device is coupled with a dynamic random access memory (DRAM) device and configured to store an operating parameter of the DRAM. In an example, the OTP memory device is configured to store data such as a process parameter, a model parameter, an operating voltage, an operating current, and the like of the DRAM; or, the OTP memory device is coupled with a central processing unit (CPU) and configured to store data such as a process parameter, a model parameter, an operating program, and the like of the CPU. The examples of the present application do not define the chips coupled with the OTP memory device.

Taking the OTP memory device being coupled with the DRAM for example, when the DRAM is powered on, the peripheral circuit of the DRAM sends the power-on signal to the peripheral circuit of the OTP memory device. The peripheral circuit of the OTP memory device receives the power-on signal and reads a plurality of correction parameter copies from the OTP memory array with the first read parameter. The first read parameter is a default read parameter after the OTP memory device is powered on.

In an example, the first read parameter comprises a first read voltage, a first read current, and a first time delay. The first read voltage is a reference voltage sensed in a read process; the first read current is a reference current in the read process; and the first time delay is a time delay required to be set in the read process because a memory cell to be read needs to be selected first, in order to match a time when a sense amplifier is enabled to read an accurate value. In an example, with reference to FIG. 4, in the OTP memory device, if many memory cells are programmed, the circuit will generate a large current, and the reference current is for limiting a current in an entire process. Moreover, the reference current is adjusted such that a read result is more accurate. In FIG. 4, a current module 410 (current_ref) is configured to provide a stable current in the read process, and ctl1/2/3 can separately adjust a ratio of a current mirror.

It is to be noted that this example is described by taking the first read parameter comprising the above-mentioned three parameters for example. The first read parameter may further comprise more or less parameters, which will not be defined in this example.

The first read parameter is the default read parameter preset in the OTP memory device, which may be construed as a universal read parameter, but affected by PVT. When the first read parameter is employed to read the memory array, the problem of inaccuracy may occur, leading to a data read error. In an example, the first read voltage is a default reference voltage, but is affected by PVT. An actual reference voltage is slightly higher than the first read voltage. When data 0 stored in the memory cell is read at the first read voltage, there may be a case where the data is not read since the actual reference voltage is high and data 1 is actually stored in the memory cell.

In examples of the present application, when the chip coupled with the OTP memory device is powered on, firstly, the first read parameter is employed to read a plurality of correction parameter copies from the memory array, and the plurality of correction parameter copies are a plurality of copies stored based on the correction parameter and are for correcting the read correction parameter. Since the plurality of correction parameter copies all point to the same correction parameter and an error occurs in reading the data stored in the memory array with the first read parameter, the correction parameter is corrected with the plurality of correction parameter copies such that a probability of occurrence of an error in correction parameter reading is reduced.

At operation 340, the plurality of correction parameter copies are corrected to output the correction parameter, wherein the correction parameter is for adjusting the first read parameter to obtain a second read parameter when reading the first memory array.

In some examples, the plurality of correction parameter copies are corrected according to the majority decision principle to output the correction parameter. The number of the correction parameter copies corresponding to each correction parameter is greater than or equal to 3. For example, the correction parameter is determined from at least three correction parameter copies according to the majority decision principle.

In an example, taking three correction parameter copies being stored for each correction parameter for example, when using the first read parameter to read at least two correction parameter copies is a first value, the first value is determined as the value of the correction parameter. Similarly, when using the first read parameter to read at least two correction parameter copies is a second value, the second value is determined as the value of the correction parameter.

Optionally, in some examples, the value of each correction parameter copy is a numerical value obtained by combining values of a plurality of data bits, and the way of acquiring the correction parameter comprises at least one of the following ways.
1, the values of a plurality of data bits of each correction parameter copy are read; and the values of the plurality of data bits are combined to obtain the number of each correction parameter copy. For example, the values of the plurality of data bits of correction parameter copy a′ are combined to obtain the correction parameter copy a′, the values of the plurality of data bits of correction parameter copy a″ are combined to obtain the correction parameter copy aΔ, and so on.

The values of the read plurality of correction parameter copies are corrected as a whole, and the value of the correction parameter is determined from the values of the plurality of correction parameter copies.

By correcting the values of the correction parameter copies as a whole, the correction efficiency of the correction parameter copies is improved, and the amount of computing resources used in the process of correcting the correction parameter copies is reduced.
2, the value of the data bit is corrected in units of the data bit.

For example, a first data bit of correction parameter copy a′, a first data bit of correction parameter copy a″, and a first data bit of correction parameter copy a″Δ are corrected to obtain the value of a first data bit of the correction parameter; and a second data bit of the correction parameter copy a′, a second data bit of the correction parameter copy aΔ, and a second data bit of the correction parameter copy a′Δ are corrected to obtain the value of a second data bit of the correction parameter.

The above operation is cycled until the values of all the data bits of the correction parameter are obtained to obtain the value of the correction parameter.

The value of each data bit is corrected by sequentially correcting the data bits one by one such that the accuracy of the correction parameter is improved, and the read correctness of the correction parameter is ensured in units of the data bit.

In some examples, the peripheral circuit comprises a multiple modular redundancy sub-circuit, and the plurality of correction parameter copies are corrected by the multiple modular redundancy sub-circuit to output the correction parameter.

The multiple modular redundancy sub-circuit is disposed to correct the plurality of correction parameter copies such that the efficiency and accuracy of correction after reading the correction parameter copies are improved, and the read efficiency of the correction parameter is improved.

Optionally, the multiple modular redundancy sub-circuit comprises a voter, and the correction parameter is determined from the plurality of correction parameter copies by the voter in the multiple modular redundancy sub-circuit. The multiple modular redundancy sub-circuit may be implemented as a triple modular redundancy sub-circuit, a quadruple modular redundancy sub-circuit, or the like. In this example, the multiple modular redundancy sub-circuit is implemented as the triple modular redundancy sub-circuit for example. Triple modular refers to three modules for performing voting in the sub-circuit. Similarly, quadruple modular refers to four modules for performing voting in the sub-circuit.

Voting is performed by the voter in the multiple modular redundancy sub-circuit on whether the read correction parameter copies are the same, and a value accounting for a large proportion is acquired from the values of the plurality of correction parameter copies as the value of the correction parameter according to a voting result. The read accuracy of the correction parameter is improved.

Optionally, the number of the correction parameter copies corresponding to the correction parameter corresponds to the number of modules for performing voting in the multiple modular redundancy sub-circuit, wherein the number of the correction parameter copies corresponding to the same correction parameter corresponds to the number of modules for performing voting in the multiple modular redundancy sub-circuit. For example, three correction parameter copies are stored with respect to correction parameter a, and the peripheral circuit comprises a triple modular redundancy sub-circuit for performing voting on the three correction parameter copies for correction.

In some examples, the number of the correction parameter copies corresponding to the correction parameter is equal to the number of modules for performing voting in the multiple modular redundancy sub-circuit; or, the number of modules for performing voting in the multiple modular redundancy sub-circuit is greater than the number of the correction parameter copies. In examples of the present application, taking the number of the correction parameter copies being equal to the number of modules for performing voting in the multiple modular redundancy sub-circuit for example, each correction parameter copy is input to at least two modules in the multiple modular redundancy sub-circuit for comparison with other correction parameter copies.

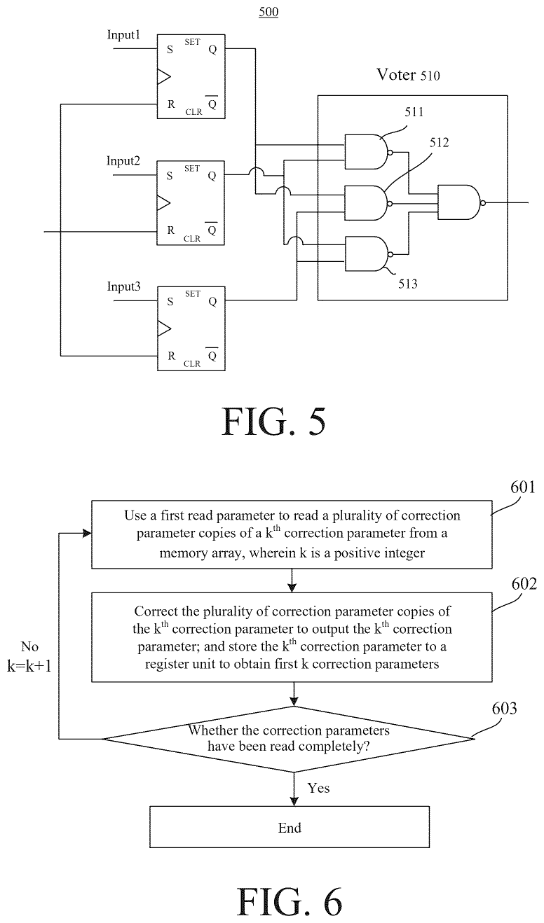

The voter in the triple modular redundancy sub-circuit comprises three modules for performing voting. FIG. 5 is a schematic diagram of a multiple modular redundancy circuit provided by one example of the present application. The multiple modular redundancy circuit shown in FIG. 5 is a triple modular redundancy sub-circuit 500.

The triple modular redundancy sub-circuit 500 comprises a voter 510, and the voter 510 comprises a module 511, a module 512, and a module 513 for performing voting.

After a first read parameter is employed to read three correction parameter copies, the three correction parameter copies are separately input into the module 511 of the voter 510. As shown in FIG. 5, the correction parameter copy 1 and the correction parameter copy 2 are input into the first module 511; the correction parameter copy 1 and the correction parameter copy 3 are input into the second module 512; and the correction parameter copy 2 and the correction parameter copy 3 are input into the third module 513.

The voter 510 determines whether the correction parameter copy 1, the correction parameter copy 2, and the correction parameter copy 3 are the same or different through the module 511, the module 512, and the module 513, respectively, such that a plurality of values are output from the three correction parameter copies according to a determination result.

In an example, the module 511 determines whether the correction parameter copy 1 and the correction parameter copy 2 are the same, and outputs 1 if yes and outputs 0 if no; the module 512 determines whether the correction parameter copy 1 and the correction parameter copy 3 are the same, and outputs 1 if yes and outputs 0 if no; and the module 513 determines whether the correction parameter copy 2 and the correction parameter copy 3 are the same, and outputs 1 if yes and outputs 0 if no. Since the value of the correction parameter copy comprises a first value or a second value, for example, the value of the correction parameter copy comprises 0 or 1, if the correction parameter copy 1, the correction parameter copy 2, and the correction parameter copy 3 have different values, the value which is in majority can be determined with numerical values output by the module 511, the module 512, and the module 513 such that the value of the correction parameter is output.

For example, if the read numerical value of the correction parameter copy 1 is 1, the read numerical value of the correction parameter copy 2 is 0, and the read numerical value of the correction parameter copy 3 is 1, the numerical value output by the module 511 is 0, the numerical value output by the module 512 is 1, and the numerical value output by the module 513 is 0. Thus, it can be determined that the value of the correction parameter copy 2 is different from the values of two correction parameter copies. For example, the values of the correction parameter copy 1 and the correction parameter copy 3 are the same, and the value of the correction parameter copy 1 and the correction parameter copy 3 is acquired as the value of the correction parameter, or the value of a certain data bit in the parameter.

The multiple modular redundancy sub-circuit is a fault-tolerant technique. Taking a triple modular redundancy circuit for example, the same operation is performed by three modules, and a correct output is determined using a majority voting system. When three input signals are ready, a clock (CLK) signal is switched, and an output at this point will be the same as most inputs. Since these three modules are independent of one another, the probability that they all have errors is very small, and therefore, the reliability of the result can be improved.

In some examples, each read parameter copy corresponds to different first read addresses, and the plurality of first read addresses are acquired, wherein an i^{th} first read address is for indicating a location of an i^{th} correction parameter copy stored in a memory array, and i is a positive integer; and the first read parameter is employed to read the plurality of first read addresses in the memory array.

In some examples, each correction parameter copy comprises n first read sub-addresses; a parameter value of the i^{th} correction parameter copy is a combination of numerical values read from the n first read sub-addresses corresponding to the i^{th} parameter copy. A numerical value read from a k^{th} first read sub-address of each correction parameter copy is acquired to obtain a plurality of numerical values, and a numerical value occurring most frequently as a value of an k^{th} bit of the correction parameter is determined from the plurality of numerical values, wherein i, n, and k are positive integers, and k≤n.

For example, the correction parameter comprises n data bits, and each correction parameter copy also comprises n data bits. Each data bit is stored in one of the first read sub-addresses, and the numerical values read from n first read sub-addresses are combined to obtain the correction parameter copy.

In an example, the correction parameter indicates a reference voltage of 4 V, which is expressed by 0100. 0100 occupies four data bits, and the four data bits are combined to obtain the correction parameter 0100. Each of three correction parameter copies occupies four data bits to express 0100, wherein each data bit is stored in one first read sub-address; and correction parameter copy a′ is stored in four first read sub-addresses and used for storing data 0, data 1, data 0, and data 0 separately. Similarly, correction parameter copy a′ is also stored in four first read sub-addresses.

The numerical value read from No. 1 first read sub-address of each correction parameter copy is acquired to obtain a plurality of numerical values, and the numerical value occurring most frequently as the value of the first bit of the correction parameter is determined from the plurality of numerical values; the numerical value read from No. 2 first read sub-address of each correction parameter copy is acquired to obtain a plurality of numerical values, and the numerical value occurring most frequently as the value of the second bit of the correction parameter is determined from the plurality of numerical values; and so on.

In conclusion, when reading a non-volatile memory device after power-on reset by the method provided by the examples of the present application, a correction parameter related to a read operation is firstly read according to a default read parameter, and since the correction parameter is stored as a plurality of parameter copies, the plurality of parameter copies are read, and the read plurality of parameter copies are corrected such that an accurate correction parameter with a small error probability is determined. A default read parameter is adjusted with the correction parameter to obtain a read parameter for reading other operating parameters. The accuracy of reading the operating parameters is improved, and the problem of low reliability of reading from an OTP memory device at a power-on stage is avoided.

In one optional example, there are a plurality of correction parameters to be read, and a plurality of correction parameter copies are stored with respect to each correction parameter.

FIG. 6 illustrates an operation method of a non-volatile memory device provided by one example of the present application. The method may be performed by a peripheral circuit of the non-volatile memory device. The method comprises at least the following operations.

At operation 601, a first read parameter is employed to read a plurality of correction parameter copies of a k^{th} correction parameter from a memory array, wherein k is a positive integer.

The correction parameter copies respectively corresponding to a plurality of correction parameters are pre-stored in the non-volatile memory device. When the value of k is greater than 1, the k^{th} correction parameter is the correction parameter which is read after the correction parameter copies of the first (k-1) correction parameters have been read completely and the first (k-1) correction parameters are corrected and stored.

When reading the plurality of correction parameter copies of the k^{th} correction parameter, firstly, a first storage address corresponding to the k^{th} correction parameter is acquired, wherein since a plurality of correction parameter copies are correspondingly stored for the k^{th} correction parameter, a plurality of first storage addresses corresponding to the k^{th} correction parameter are acquired, and each first storage address corresponds to the storage location of one correction parameter copy in the memory array.

In some examples, the first storage address is address data stored at a preset storage location of the non-volatile memory device. For example, the first storage address is pre-stored in a register of the non-volatile memory device. The first storage address is acquired from the register and input to a decoder for decoding to obtain path data of the first storage address. The path data is used for locating a memory cell corresponding to the first storage address in the memory array. The first read parameter is employed to read data stored in a memory cell from the memory array according to the path data. The first read parameter is employed to read data stored in memory cells respectively corresponding to a plurality of first storage addresses corresponding to the k^{th} correction parameter, e.g., a plurality of correction parameter copies of the k^{th} correction parameter.

At operation 602, the plurality of correction parameter copies of the k^{th} correction parameter are corrected to output the k^{th} correction parameter; and the k^{th} correction parameter is stored to the register unit to obtain first k correction parameters.

The plurality of correction parameter copies of the k^{th} correction parameter are input to a multiple modular redundancy sub-circuit, and the plurality of correction parameter copies are corrected to obtain the k^{th} correction parameter.

The multiple modular redundancy sub-circuit is configured to determine a value accounting for the largest proportion as the numerical value of the correction parameter from the values of the plurality of correction parameter copies according to the majority decision principle. For example, the multiple modular redundancy sub-circuit is configured to perform voting on the values of the plurality of correction parameter copies and acquire a value in majority as the value of the correction parameter from the values of the plurality of correction parameter copies.

After the k^{th} correction parameter is determined, the k^{th} correction parameter is stored to the register unit to obtain first k correction parameters.

At operation 603, whether the correction parameters are read completely is determined.

When the correction parameters are not read completely, k=k+1 and operation 601 is performed continuously until the correction parameters are read completely.

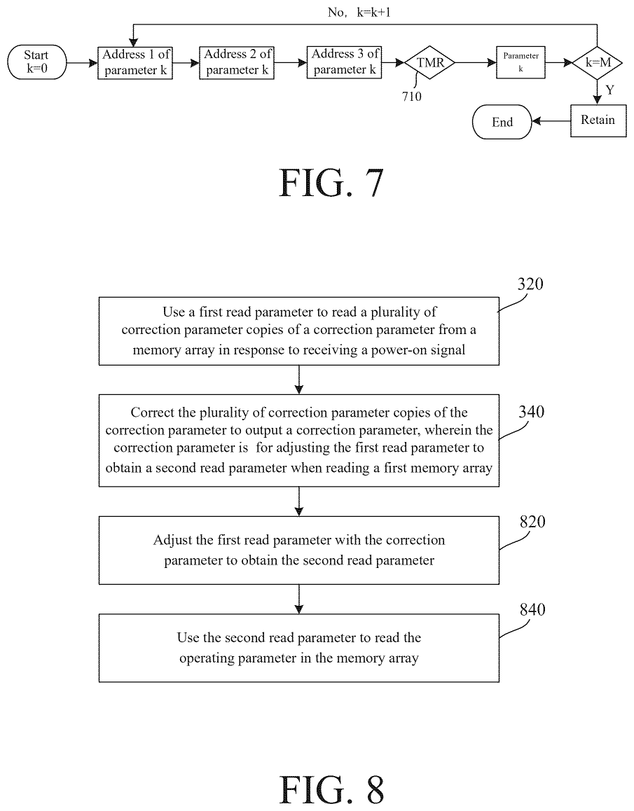

In an example, with reference to FIG. 7, it shows a schematic diagram of a read process of a correction parameter provided by one example of the present application. As shown in FIG. 7, firstly, when a read is started upon receiving a power-on signal, k=0, and the read is performed from the 0^{th} parameter.

Taking three correction parameter copies being stored for each correction parameter for example, when the k^{th} correction parameter is read, three correction parameter copies are stored for the k^{th} correction parameter, and each correction parameter copy corresponds to one storage address. As shown in FIG. 7, reads are sequentially performed from address 1 of the correction parameter k, address 2 of the correction parameter k, and address 3 of the correction parameter k to obtain correction parameter copy k′ from the address 1, correction parameter copy kΔ from the address 2, and correction parameter copy k′″ from the address 3.

The correction parameter copies k′, k″, and k′″ are separately input to a triple modular redundancy circuit 710. The three correction parameter copies are corrected by the triple modular redundancy circuit 710, and a value accounting for the highest proportion is determined from the correction parameter copies k′, kΔ, and k′Δ as the value of the correction parameter k.

The value of the correction parameter k is stored to the register unit, and whether k is equal to M is determined, wherein M is a total number of correction parameters. For example, there are a total of M correction parameters, and each correction parameter comprises 3 correction parameter copies.

A triple modular redundancy sub-circuit is added to the peripheral circuit. Each correction parameter corresponds to three correction parameter copies. The whole POR_READ process is divided into two parts. A first part requires to access and read the addresses of the related correction parameter copies and load a final result by the TMR. A second part is to read an operating parameter with a read parameter which is corrected with the correction parameter.

In conclusion, when reading a memory device after power-on reset by the method provided by the examples of the present application, a correction parameter related to a read operation is firstly read according to a default read parameter, and since the correction parameter is stored as a plurality of parameter copies, the plurality of parameter copies are read, and the read plurality of parameter copies are corrected such that an accurate correction parameter with a small error probability is determined. A default read parameter is adjusted with the correction parameter to obtain a read parameter for reading other operating parameters. The accuracy of reading the operating parameters is improved, and the problem of low reliability of reading from an OTP memory device at a power-on stage is avoided.

According to the method provided by the examples of the present application, the correction parameter copies respectively corresponding to a plurality of correction parameters are sequentially read in order, and the plurality of correction parameters are sequentially obtained and stored to the register unit. The read accuracy and efficiency of the correction parameters are improved.

In some examples, the non-volatile memory device is configured to store an operating parameter corresponding to a chip coupled therewith. FIG. 8 illustrates an operation method of a non-volatile memory device provided by another example of the present application. The method may be performed by a peripheral circuit of the non-volatile memory device. The method comprises at least the following operations after the operation 340 shown in FIG. 3.

At operation 820, the first read parameter is adjusted with the correction parameter to obtain the second read parameter.

In some examples, when the first read parameter is adjusted with the correction parameter, at least one of the following adjustment ways are included.
1, the correction parameter stored in the non-volatile memory device is read parameter data corresponding to PVT. Therefore, after the correction parameter is read directly according to the PVT, the correction parameter corresponding to the PVT is applied as the second read parameter.

For example, the correction parameter is a read parameter stored according to a correspondence with the PVT. For example, correction parameter a corresponds to process 1, voltage 5 V, and temperature 40°, and the correction parameter a comprises reference voltage, voltage and current, and time delay data. Therefore, after the correction parameter a is read according to the PVT, the correction parameter a is directly applied as the second read parameter.
2, the correction parameter stored in the non-volatile memory device is an adjustment parameter corresponding to the PVT. Therefore, after the correction parameter is acquired, the correction parameter is adjusted on the basis of the first read parameter to obtain the second read parameter.

For example, the correction parameter is an adjustment parameter stored according to a characteristic corresponding to the PVT in the memory device. For example, correction parameter b corresponds to process 1, voltage 5 V, and temperature 40°, and the correction parameter b indicates that the reference voltage is increased by 0.2. After the correction parameter b is read according to the PVT, a reference voltage in the first read parameter is directly multiplied by 1.2 to be applied as a reference voltage in the second read parameter, and a reference current and a time delay in the first read parameter are directly applied as a reference current and a time delay in the second read parameter.

It is to be noted that the above-mentioned way of acquiring the second read parameter is merely an example, which will not be defined in the examples of the present application.

At operation 840, the second read parameter is employed to read the operating parameter in the memory array.

The operating parameter is data stored in the non-volatile memory device for indicating the operating of a chip.

In some examples, the above-mentioned non-volatile memory device is implemented as an OTP memory device. The OTP memory device is coupled with other chips and configured to provide the operating parameter to other chips at power-on reset.

After the first read parameter is adjusted to obtain the second read parameter, the second read parameter is a read parameter which is superior to the first read parameter after calibration. Therefore, the operating parameter in the memory array is directly read with the second read parameter.

Optionally, a second read address is acquired, wherein the second read address is for indicating a location of the operating parameter stored in the memory array, and the second read parameter is employed to read the operating parameter from the second read address in the memory array.

The operating parameter refers to a configuration and setting parameter required to be used when the chip or the system is operating. These operating parameters might comprise a working frequency, a voltage threshold, a clock setting, calibration data, a calibration curve, and the like of the chip. The operating parameter is typically set at an apparatus manufacturing or system initialization stage and will not be modified after it has been set, and thus is stored by the OTP memory device.

In conclusion, when reading a memory device after power-on reset by the method provided by the examples of the present application, a correction parameter is read, and a first read parameter is corrected with the correction parameter to obtain a second read parameter. Thus, an operating parameter of operating of the chip is read with the second read parameter. The read accuracy of the operating parameter is improved.

Examples of the present application further provide a volatile memory device, coupled with a non-volatile memory device and comprising a memory array and a peripheral circuit.

The peripheral circuit is configured to:
after the volatile memory device is powered on, send a power-on signal to the non-volatile memory device, wherein the power-on signal is for instructing the non-volatile memory device to use a first read parameter to read a plurality of correction parameter copies from a memory array of the non-volatile memory device, and correct the plurality of correction parameter copies of the correction parameter to output a correction parameter, and determine a second read parameter based on the correction parameter and then read an operating parameter with the second read parameter;
receive the operating parameter sent by the non-volatile memory device; and read the memory array based on the operating parameter.

In one optional example, the peripheral circuit of the volatile memory device is coupled with a peripheral circuit of the non-volatile memory device.

The peripheral circuit is configured to: after the volatile memory device is powered on, send the power-on signal to the peripheral circuit of the non-volatile memory device.

In one optional example, the peripheral circuit is further configured to: read the memory array based on a read voltage, a read current, and a time delay in the operating parameter.

In one optional example, the non-volatile memory device coupled with the volatile memory device is implemented as a one time program (OTP) memory device.

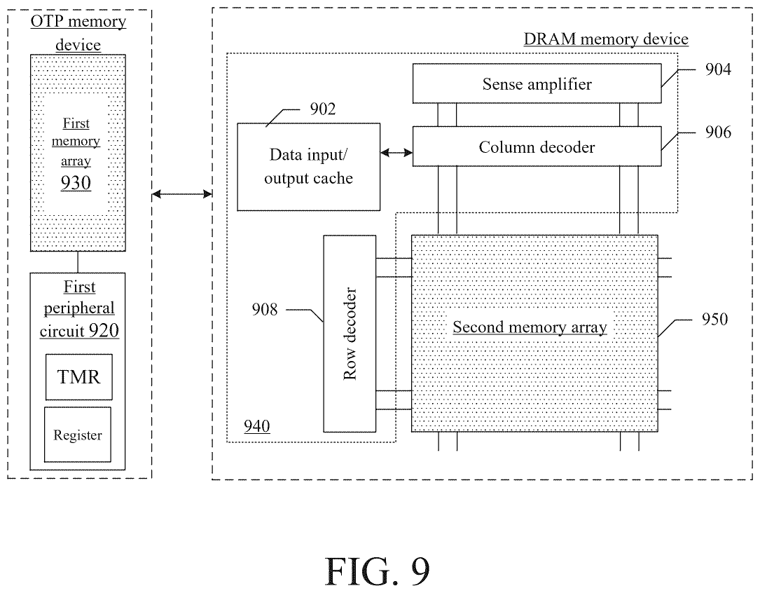

FIG. 9 is a structural schematic diagram of a memory device provided by examples of the present application. As shown in FIG. 9, a DRAM is coupled with an OTP memory device.

The OTP memory device comprises a first peripheral circuit 920 and a first memory array 930, and the DRAM comprises a second peripheral circuit 940 and a second memory array 950.

The OTP memory device is configured to provide an operating parameter of operating to the DRAM, wherein the first peripheral circuit 920 comprises a triple modular redundancy sub-circuit TMR and a register; and the operating parameter and correction parameter copies of a correction parameter used by the OTP memory device at a power-on reset read stage are stored in the first memory array 930.

When the DRAM is powered on, the second peripheral circuit 940 sends a power-on signal to the first peripheral circuit 920 of the OTP memory device through an input/output circuit 916.

After receiving the power-on signal, the OTP memory device acquires a first read address of the correction parameter copies, and uses a first read parameter to read a plurality of correction parameter copies from the first read address of the first memory array 930. The plurality of correction parameter copies are corrected by the TMR to obtain the correction parameter, and the correction parameter is stored to the register.

After the correction parameter has been read completely, the first read parameter is adjusted based on the correction parameter to obtain a second read parameter, and the operating parameter stored in the first memory array 930 is read based on the second read parameter. Moreover, the read operating parameter is sent to the second peripheral circuit 940.

The second peripheral circuit 940 is configured to write and read data to and from the second memory array 950.

The second peripheral circuit 940 comprises a data input/output cache 902, a sense amplifier 904, a column decoder 906, and a row decoder 908. It will be appreciated that in some examples, an additional second peripheral circuit not shown in FIG. 9 may be further included, such as a register, a data bus, or the like.

The sense amplifier 904 may be configured to read and program (write) data from and to the second memory array 950 according to a control signal. In one example, the sense amplifier 904 may store one page of program data (write data) to be programmed into one page of the second memory array 950. In another example, the sense amplifier 904 may perform a program verify operation to ensure that the data has been properly programmed into the memory cell coupled to a selected word line. In yet another example, the sense amplifier 904 may also sense a low power signal from the bit line that represents a data bit stored in the memory cell, and amplifies a small voltage swing to a recognizable logic level in the read operation.

The column decoder 906 may be configured to select one or more memory strings by applying a bit line voltage.

The row decoder 908 may be configured to select/unselect a block of the second memory array 950 and select/unselect a word line of the block. The row decoder 908 may be further configured to drive the word line using a word line voltage (V_{WL}). In some implementations, the row decoder 908 may also select/unselect and drive source select gate lines and drain select gate lines. In an example, the row decoder 908 is configured to perform an erase operation on memory cells coupled to (one or more) selected word lines.

It is to be noted that the second peripheral circuit 940 is configured to perform an operation method of a memory device provided by examples of the present disclosure on selected memory cells in a plurality of memory cell rows.

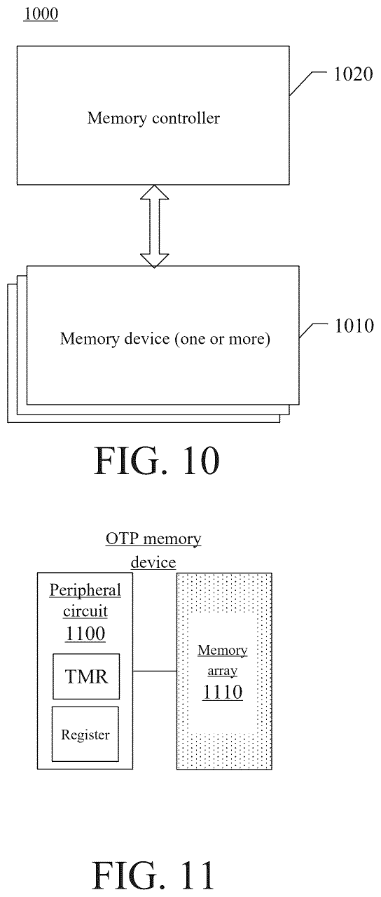

FIG. 10 is a block structural diagram of a memory system provided by an example of the present application. As shown in FIG. 10, the memory system 1000 comprises: one or more memory devices 1010; and a memory controller 1020 coupled to the memory device 1010 and configured to control the memory device 1010.

The memory system 1000 may be a mobile phone, a desktop computer, a laptop computer, a tablet, a vehicle computer, a gaming console, a printer, a positioning device, a wearable electronic device, a smart sensor, a Virtual Reality (VR) apparatus, an Augmented Reality (AR) apparatus, or any other suitable electronic devices having memory devices therein.

Optionally, the memory system 1000 may comprise a host and a memory sub-system, wherein the memory sub-system has one or more memory devices 1010 and a memory controller 1020. The host may be a processor of an electronic device (e.g., a central processing unit (CPU), or a system on chip (SoC) (e.g., an application processor (AP)). The host may be configured to send data to the memory device 1010. Alternatively, the host may be configured to receive data from the memory device 1010.

According to some implementations, the memory controller 1020 is further coupled to the host. The memory controller 1020 may manage data stored in the memory device 1010, and communicate with the host.

In some implementations, the memory controller 1020 is designed for operating in a low duty-cycle environment, such as Secure Digital (SD) cards, Compact Flash (CF) Cards, Universal Serial Bus (USB) flash drives, or other media for use in electronic devices, such as personal computers, digital cameras, mobile phones, etc.

In some implementations, the memory controller 1020 is designed for operating in a high duty-cycle environment, e.g., a Solid State Disk (SSD) or an embedded Multi Media Card (eMMC) which is used as a data memory device for a mobile device, such as a smartphone, a tablet computer, and a laptop computer, etc., and an enterprise memory array.

The memory controller 1020 may be configured to control operations of the memory device 1010, such as read, erase, and program operations. The memory controller 1020 may be further configured to manage various functions with respect to data stored or to be stored in the memory device 1010, including, but not limited to, bad-block management, garbage collection, logical-to-physical address translation, wear leveling, etc. In some implementations, the memory controller 1020 is further configured to process Error Correcting Code (ECCs) with respect to the data read from or written to the memory devices 1010.

The memory controller 1020 may further execute any other suitable functions, for example, formatting the memory device 1010. The memory controller 1020 may communicate with an external apparatus according to a particular communication protocol.

The memory controller 1020 and the one or more memory devices 1010 may be integrated to various types of memory apparatuses, for example, be comprised in the same package (such as a Universal Flash Storage (UFS) package or an eMMC package). For example, the memory system 1000 may be implemented and packaged into different types of end electronic products.

Schematically, the memory controller 1020 and a single memory device 1010 may be integrated into a memory card. The memory card may comprise a personal computer memory card international association (PCMCIA, PC) card, a CF card, a Smart Media (SM) card, a memory stick, a multimedia card, an SD card, a UFS, etc. The memory card may further comprise a memory card connector coupling the memory card with the host.

In an example, the memory controller 1020 and the plurality of memory devices 1010 may be integrated into a solid state disk (SSD). In some implementations, the memory capacity and/or operation speed of the solid state disk are greater than those of the memory card.

It may be understood that, the memory controller 1020 may perform the operation method of a memory device provided in any one of the examples of the present disclosure.

The above-mentioned memory device 1010 may be implemented as a volatile memory device involved in the examples of the present application, or may be implemented as a non-volatile memory device involved in the examples of the present application.

Examples of the present application provide a control circuit. The control circuit comprises at least one of a programmable logic circuit or a program instruction. The control circuit may be configured to implement the operation method of a non-volatile memory device provided by the aforementioned examples of the present application.

In an example, as shown in FIG. 11, the non-volatile memory device comprises a peripheral circuit 1100 and a memory array 1110.

The peripheral circuit 1100 is configured to:
use a first read parameter to read a plurality of correction parameter copies of a correction parameter from the memory array 1110 in response to receiving a power-on signal, wherein the plurality of correction parameter copies are copies stored with respect to the correction parameter; and
correct the plurality of correction parameter copies of the correction parameter to output the correction parameter, wherein the correction parameter is for adjusting the first read parameter to obtain a second read parameter when reading the memory array 1110.

In one optional example, the non-volatile memory device comprises a one time program (OTP) memory device.

In one optional example, the peripheral circuit 1100 comprises a multiple modular redundancy sub-circuit.

The peripheral circuit 1100 is further configured to:
correct, by the multiple modular redundancy sub-circuit, the plurality of correction parameter copies to output the correction parameter.

In one optional example, the multiple modular redundancy sub-circuit comprises a voter; and
the peripheral circuit 1100 is further configured to:
determine, by the voter in the multiple modular redundancy sub-circuit, the correction parameter from the plurality of correction parameter copies.

In one optional example, each correction parameter copy comprises n first read sub-addresses; a parameter value of an i^{th} correction parameter copy is a combination of numerical values read from the n first read sub-addresses corresponding to the i^{th} parameter copy; and the peripheral circuit 1100 is further configured to:
acquire a numerical value read from a k^{th} first read sub-address of each correction parameter copy to obtain a plurality of numerical values, and determine, from the plurality of numerical values, a numerical value occurring most frequently as a value of an i^{th} bit of the correction parameter, wherein i, n, and k are positive integers, and k≤n.

In one optional example, the peripheral circuit 1100 is further configured to:
acquire a plurality of first read addresses, wherein an i^{th} first read address is for indicating a location of the i^{th} correction parameter copy stored in the memory array 1110, and i is a positive integer; and
use the first read parameter to read the plurality of first read addresses in the memory array 1110.

In one optional example, the number of the correction parameter copies corresponding to the correction parameter corresponds to the number of modules for performing voting in the multiple modular redundancy sub-circuit.

In one optional example, the peripheral circuit 1100 further comprises a register unit.

The peripheral circuit 1100 is further configured to:
use the first read parameter to read a plurality of correction parameter copies of an m^{th} correction parameter from the memory array 1110, wherein m is a positive integer;
correct the plurality of correction parameter copies of the m^{th} correction parameter to output the m^{th} correction parameter; store the m^{th} correction parameter to the register unit to obtain first m correction parameters;
if the correction parameters are not read completely, read a plurality of correction parameter copies of an (m+1)^{th} correction parameter from the memory array 1110;
correct the plurality of correction parameter copies of the (m+1)^{th} correction parameter to output the (m+1)^{th} correction parameter; and store the (m+1)^{th} correction parameter to the register unit to obtain first m+1 correction parameters until all the correction parameters are read completely.

In one optional example, the peripheral circuit 1100 is further configured to:
adjust the first read parameter with the correction parameter to obtain the second read parameter; and
use the second read parameter to read an operating parameter in the memory array 1110, wherein the operating parameter is data stored in the memory device for indicating the operating of a chip.

In one optional example, the peripheral circuit 1100 is further configured to:
acquire a second read address, wherein the second read address is for indicating a location of the operating parameter stored in the memory array 1110; and
use the second read parameter to read the operating parameter from the second read address in the memory array 1110.

Examples of the present application provide an electronic device. The electronic device comprises:
one or more non-volatile memory devices or volatile memory devices described in any of the above-mentioned examples, and
a memory controller coupled to the non-volatile memory devices or the volatile memory devices and configured to control the non-volatile memory devices or the volatile memory devices.

Examples of the present application provide a computer readable storage medium which stores instructions therein, where the instructions achieve the program method of the memory device provided by the preceding examples of the present application when controlling running on a circuit.

In the present application, the terms “first” and “second” are only for the purpose of description, and cannot be construed as indicating or implying relative importance. The term “at least one” means one or more, and the term “a plurality of” means two or more, unless otherwise defined clearly.

The term “and/or” in the present application is merely an association relationship describing related objects, which means that there may be three relationships, for example, A and/or B may indicate three cases: A exists alone, A and B exist simultaneously, and B exists alone. In addition, the character “/” herein generally indicates that the related objects are in an “or” relationship.

The above are only examples of the present application, and are not used to limit the present application. Any modifications, equivalent replacements and improvements and the like made within the spirit and principle of the present application shall be included within the scope of protection of the present application.

What is claimed is:

1. A non-volatile memory device, comprising:
a memory array; and
a peripheral circuit configured to:
use a first read parameter to read a plurality of correction parameter copies of a correction parameter from the memory array in response to receiving a power-on signal, wherein the plurality of correction parameter copies are copies stored with respect to the correction parameter; and
correct the plurality of correction parameter copies of the correction parameter to output the correction parameter, wherein the correction parameter is for adjusting the first read parameter to obtain a second read parameter when reading the memory array.

2. The memory device of claim 1, wherein the non-volatile memory device comprises a one time program (OTP) memory device.

3. The memory device of claim 1, wherein the peripheral circuit comprises a multiple modular redundancy sub-circuit, and the peripheral circuit is further configured to:
correct, by the multiple modular redundancy sub-circuit, the plurality of correction parameter copies to output the correction parameter.

4. The memory device of claim 3, wherein the multiple modular redundancy sub-circuit comprises a voter, and the peripheral circuit is further configured to:
determine, by the voter in the multiple modular redundancy sub-circuit, the correction parameter from the plurality of correction parameter copies.

5. The memory device of claim 1, wherein each correction parameter copy comprises n first read sub-addresses, a parameter value of an i^{th} correction parameter copy is a combination of numerical values read from the n first read sub-addresses corresponding to the i^{th} parameter copy, and the peripheral circuit is further configured to:
acquire a numerical value read from a k^{th} first read sub-address of each correction parameter copy to obtain a plurality of numerical values, and determine, from the plurality of numerical values, a numerical value occurring most frequently as a value of an k^{th} bit of the correction parameter, wherein i, n, and k are positive integers, and k≤n.

6. The memory device of claim 1, wherein the peripheral circuit is further configured to:
acquire a plurality of first read addresses, wherein an i^{th} first read address is for indicating a location of the i^{th} correction parameter copy stored in the memory array, and i is a positive integer; and
use the first read parameter to read the plurality of first read addresses in the memory array.

7. The memory device of claim 3, wherein:
a number of the correction parameter copies corresponding to the correction parameter corresponds to a number of modules for performing voting in the multiple modular redundancy sub-circuit.

8. The memory device of claim 1, wherein the peripheral circuit further comprises a register unit, and the peripheral circuit is further configured to:
use the first read parameter to read a plurality of correction parameter copies of an m^{th} correction parameter from the memory array, wherein m is a positive integer;
correct the plurality of correction parameter copies of the m^{th} correction parameter to output the m^{th} correction parameter;
store the m^{th} correction parameter to the register unit to obtain first m correction parameters;
if the correction parameters are not read completely, read a plurality of correction parameter copies of an (m+1)^{th} correction parameter from the memory array;
correct the plurality of correction parameter copies of the (m+1)^{th} correction parameter to output the (m+1)^{th} correction parameter; and
store the (m+1)^{th} correction parameter to the register unit to obtain first m+1 correction parameters until all the correction parameters are read completely.

9. The memory device of claim 1, wherein the peripheral circuit is further configured to:
adjust the first read parameter with the correction parameter to obtain the second read parameter; and
use the second read parameter to read an operating parameter in the memory array, wherein the operating parameter is data stored in the memory device for indicating the operating of a chip.

10. The memory device of claim 9, wherein the peripheral circuit is further configured to:
acquire a second read address, wherein the second read address is for indicating a location of the operating parameter stored in the memory array; and
use the second read parameter to read the operating parameter from the second read address in the memory array.

11. A volatile memory device, coupled with a non-volatile memory device and comprising:
a memory array; and
a peripheral circuit, configured to:
after the volatile memory device is powered on, send a power-on signal to the non-volatile memory device, wherein the power-on signal is for instructing the non-volatile memory device to use a first read parameter to read a plurality of correction parameter copies of a correction parameter from a memory array of the non-volatile memory device, correct the plurality of correction parameter copies of the correction parameter to output a correction parameter, and determine a second read parameter based on the correction parameter and then read an operating parameter with the second read parameter;
receive the operating parameter sent by the non-volatile memory device; and
read the memory array based on the operating parameter.

12. The memory device of claim 11, wherein the peripheral circuit is coupled with a peripheral circuit of the non-volatile memory device and further configured to:
after the volatile memory device is powered on, send the power-on signal to the peripheral circuit of the non-volatile memory device.

13. The memory device of claim 11, wherein the peripheral circuit is further configured to:
read the memory array based on a read voltage, a read current, and a time delay in the operating parameter.

14. The memory device of claim 11, wherein:
the non-volatile memory device coupled with the volatile memory device is implemented as a one time program (OTP) memory device.

15. An operation method of a non-volatile memory device, comprising:
using a first read parameter to read a plurality of correction parameter copies of a correction parameter from a memory array in response to receiving a power-on signal, wherein the plurality of correction parameter copies are copies stored with respect to the correction parameter; and
correcting the plurality of correction parameter copies to output the correction parameter, wherein the correction parameter is for adjusting the first read parameter to obtain a second read parameter when reading the memory array.

16. The method of claim 15, wherein the non-volatile memory device comprises a one time program (OTP) memory device.

17. The method of claim 15, wherein the using the first read parameter to read the plurality of correction parameter copies of a correction parameter from the memory array comprises:
acquiring a plurality of first read addresses, wherein an i^{th} first read address is for indicating a location of an i^{th} correction parameter copy stored in the memory array, and i is a positive integer; and
using the first read parameter to read from the plurality of first read addresses in the memory array.

18. The method of claim 15, wherein each correction parameter copy comprises n first read sub-addresses; a parameter value of an i^{th} correction parameter copy is a combination of numerical values read from the n first read sub-addresses corresponding to the i^{th} parameter copy; and
the correcting the plurality of correction parameter copies to output the correction parameter comprises:
acquiring a numerical value read from a k^{th} first read sub-address of each correction parameter copy to obtain a plurality of numerical values; and
determining, from the plurality of numerical values, a numerical value occurring most frequently as a value of an i^{th} bit of the correction parameter, wherein i, n, and k are positive integers, and k≤n.

19. The method of claim 15, wherein:
the non-volatile memory device comprises a multiple modular redundancy sub-circuit; and a number of the stored correction parameter copies corresponds to a number of modules for performing voting in the multiple modular redundancy sub-circuit.

20. The method of claim 15, further comprising:
using the first read parameter to read a plurality of correction parameter copies of an m^{th} correction parameter from the memory array, wherein m is a positive integer;
correcting the plurality of correction parameter copies of the m^{th} correction parameter to output the m^{th} correction parameter;
storing the m^{th} correction parameter to obtain first m correction parameters;
if the correction parameters are not read completely, reading a plurality of correction parameter copies of an (m+1)^{th} correction parameter from the memory array;
correcting the plurality of correction parameter copies of the (m+1)^{th} correction parameter to output the (m+1)^{th} correction parameter; and
storing the (m+1)^{th} correction parameter to obtain first m+1 correction parameters until all the correction parameters are read completely.
